(19) United States
(12) Patent Application Publication
(10) Pub. No.: US 2026/0086121 A1
(43) Pub. Date: Mar. 26, 2026

(54) RECONFIGURABLE PROBE CARD FOR CRYOGENIC APPLICATIONS

(71) Applicant: International Business Machines Corporation, Armonk, NY (US)

(72) Inventors: Lisa Sommer, Hagen (DE); Stephan Paredes, Zurich (CH); Matthias Mergenthaler, Zurich (CH); Andreas Fuhrer Janett, Zurich (CH)

(21) Appl. No.: 18/898,056

(22) Filed: Sep. 26, 2024

(51) Int. Cl. G01R 1/073

(52) U.S. Cl. CPC G01R 1/07342; G01R 1/07364

(57) ABSTRACT

A probe card includes a printed circuit board configured to transfer electrical signals to test and measurement circuitry, and a plurality of retractable needles mounted on the printed circuit board and configured to transfer the electrical signals from a chip via the printed circuit board. A plurality of actuators are mounted on the printed circuit board, each actuator configured to operate at cryogenic temperatures, engage a corresponding retractable needle of the plurality of retractable needles and to adjust a position of the engaged retractable needle to contact a pad on the chip.

### STATEMENT REGARDING GOVERNMENT SPONSORED RESEARCH OR DEVELOPMENT

This invention was made with Government support under NCCR SPIN 2020_65 awarded by EU Funded Projects (Switzerland). The Government has certain rights to this invention.

### BACKGROUND

The present invention relates generally to the electrical, electronic and computer arts and, more particularly, to characterization tools and devices.

Cryogenic electronics/logic for classical and quantum computing are becoming important technologies. For these technologies, cryogenic probe stations are a standard tool in semiconductor cryogenic device characterization and in their development cycle. Conventional probe cards having a fixed layout (a layout specific to the contact pad design and configuration of a given device) require multiple probe cards with different pad layouts to support a variety of devices, resulting in higher costs. Moreover, for a given measurement cycle, only one contact pad arrangement per device is possible, resulting in slower processing times as the cryostat needs to go through a thermal cycle to replace a probe card.

In addition, conventional probe cards are typically developed with room temperature operation in mind and therefore lack cryogenic compatibility, such as compatibilities related to size, thermalization, turn-around time, handling and the like. Translation of the device with respect to the probe card may also be required, adding a heat load at cryogenic temperatures, and leading to slower thermalization which leads to longer measurement times. Single homogeneous wafer/chip height is also required; that is, only single substrate testing is possible.

### BRIEF SUMMARY

Principles of the invention provide systems and techniques for reconfigurable probe card for cryogenic applications. In one aspect, an exemplary method includes the operations of cooling a cryostat to cryogenic temperatures; configuring a set of retractable needles of a probe card according to a test plan for a given device during testing at the cryogenic temperatures; and testing the given device using the set of retractable needles.

In one aspect, a probe card comprises a printed circuit board configured to transfer electrical signals to test and measurement circuitry; a plurality of retractable needles mounted on the printed circuit board and configured to transfer the electrical signals from a chip via the printed circuit board; and a plurality of actuators mounted on the printed circuit board, each actuator configured to operate at cryogenic temperatures, engage a corresponding retractable needle of the plurality of retractable needles and to adjust a position of the engaged retractable needle to contact a pad on the chip.

In one aspect, a system comprises a chip under test; a controller configured to control test activities for the chip under test; and a probe card comprising a printed circuit board configured to transfer electrical signals to test and measurement circuitry; a plurality of retractable needles mounted on the printed circuit board and configured to transfer the electrical signals from the chip via the printed circuit board under a control of the controller; and a plurality of actuators mounted on the printed circuit board, each actuator configured to operate at cryogenic temperatures, engage a corresponding retractable needle of the plurality of retractable needles and to adjust a position of the engaged retractable needle to contact a pad on the chip.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
a cryogenically compatible probe card;
a reconfigurable probe card that enables different device tests, and tests of different devices and device layouts at cryogenic temperatures without warm up (thermal cycling);
a reconfigurable probe card that enables in-line and end-of-line characterization of semiconductor and quantum devices;
elimination of the need for multiple probe cards with different pad layouts, resulting in lower costs, and lower test and development time;
adjustable probe needle height, which enables pre-packaged testing of chips with different thicknesses and different chiplet combinations;
detachable needles that enable testing of isolated devices without unused, detached needles introducing thermal noise or conduction over connection to room temperature components;
a pogo pin array that covers substantially the entire area of the device that is under test, thereby eliminating the need for translation or motion of the device under test with respect to the probe card and eliminating the resulting additional heat load such motion would generate;
an array of configurable needles that can cover a larger segment of a given area of a device or multiple devices, enabling avoiding/minimizing a repositioning of the probe card;
smaller probe card footprint due to on-board multiplexer or other electronic circuitry;
probe needles with different functionality (i.e., different types of needles, such as radio frequency needles, direct current needles and the like) that can be activated and deactivated in-situ in a controlled way;
elimination of the need for z-axis adjustment of the probe needles and the device(s) under test (by having a small movement via the actuators, the needle planarization, which has to be done for building a probe card with fixed needles, is not needed with the reconfigurable probe card);
example embodiments provide statistical cryogenic feedback for semiconductor and quantum devices (e.g., in-line and end-of-line characterization of semiconductor and quantum devices);
possible to electrostatically tune/gate a device without contact (no galvanic contact, but tunable distance);
faster device testing in the device development cycle (materials, geometries, fabrication process, four-terminal sensing, critical temperature (Tc) measurement and the like) and production cycle;
elimination of restrictions for having only one contact pad arrangement per device for a given measurement cycle, resulting in faster processing times as the cryostat does not need to go through a thermal cycle to replace a probe card;
support for chips with different substrate heights enabling measurements and the testing and interconnection of such chips at the same time prior to mounting the chips on an interposer;
fast cryogenic in-line and end-of-line characterization of cryogenic semiconductor and/or quantum devices (within one cool down of the cryostat); and
circuitry residing on a probe card for enabling, for example, system-level testing.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 illustrates the components of a conventional probe card;

FIG. 2 illustrates an example standard cryogenic device characterization platform with a fixed chip to board interface (no probe card);

FIG. 3 illustrates a conventional technique for interfacing to a chip under test in a cryogenic environment (for example, under 77 Kelvin (K)) with a first fixed probe card;

FIG. 4 illustrates a conventional technique for interfacing to a chip under test in a cryogenic environment with a second fixed probe card;

FIG. 5 is an overview of a reconfigurable probe card, in accordance with example embodiments;

FIG. 6 illustrates the reconfigurable probe card configured to serve as fixed probe card;

FIG. 7 illustrates the reconfigurable probe card configured to serve as fixed probe card;

FIG. 8 illustrates the reconfigurable probe card configured to probe heterogenous chips, such as chips having different thicknesses, in accordance with example embodiments;

FIGS. 9A-9B illustrate a retractable needle in the down and up positions, respectively, in accordance with example embodiments;

FIG. 10 illustrates a first example embodiment of the reconfigurable probe card incorporating a stacked piezo actuated retractable needle;

FIG. 11 illustrates a second example embodiment of the reconfigurable probe card incorporating a thin film piezo bimorph (or bi-metal) actuated retractable needle, in accordance with example embodiments;

FIGS. 12A-12B illustrate a third example embodiment of the reconfigurable probe card incorporating a bellows-actuated retractable needle, in accordance with example embodiments;

FIG. 13 illustrates a fourth example embodiment of the reconfigurable probe card incorporating a movable wedge actuated retractable needle, in accordance with example embodiments;

FIG. 14 illustrates a fifth example embodiment of the reconfigurable probe card incorporating a coil actuated retractable needle, in accordance with example embodiments;

FIG. 15 depicts a computing environment according to an embodiment of the present invention; and

FIG. 16 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

In example embodiments, a reconfigurable probe card is disclosed. In one or more embodiments, the probe card is configured to rapidly reconfigure during operation and may be implemented as a component of a probe station that is user-accessible. Example embodiments of the probe card are a tool/device suitable for fast cryogenic inline/end-of-line characterization of cryogenic semiconductor or quantum devices during one cool down of the cryostat. Through lifting and lowering mechanisms attached to individual probe needles, it is possible to mechanically actuate the needles, resulting in an in-situ configurable probe card that can adapt to various bond pad layouts, different chip surface levels, different wafer/chip topologies and the like. (It is noted that, for cryogenic environments, the actuators must typically be capable of operation at cryogenic temperatures.)

Example embodiments provide the possibility to measure and test various device types with different measurement configurations (for example, at room temperature, cryogenic temperatures and the like), the possibility to characterize devices having different bond pad patterns and provide for inline tests during the fabrication process to verify that the process worked properly. The described flexibility enables faster device testing in the device development cycle (materials, geometries, fab process, four-terminal sensing, Tc measurement and the like). In addition, a configurable interposer in conjunction with height adjustable needles enables in-line and end-of-line chiplet testing before permanently mounting the chiplets on a fixed interposer, that is, testing before assembly. “Chiplet” is used in its ordinary sense to refer to a small, modular chip that performs a specific function such as a processor core, a memory block, an I/O driver, a signal processing unit, or the like.

### Paths to Problem Mitigation

In example embodiments, the needles (also referred to as probe needles and probes herein) of a probe card are configured to be in-situ reconfigurable (single needle or predefined needle array/segment). The needles can be wedge-lifted, pushed down via actuators, and the like, as described more fully below. Example embodiments utilize an array with individual activatable needles or pogo pins, enabling radio frequency (RF) compatibility, potentially smaller footprint, and the like. By detaching needles from the device under test, a fully decoupled test device can be tested (eliminating thermal noise, conduction over the connection to the room temperature environment and the like). Arrays of configurable needles can cover a larger segment of a given area with multiple devices to avoid/minimize repositioning of the probe card. Pogo pin arrays that cover large areas of a device or set of devices eliminate the need for translation or motion of the device with respect to the probe card and eliminate the resulting additional heat load that such motion would generate. It is possible to electrostatically tune/gate a device without contact (no galvanic contact, but tunable distance). By having the ability to vertically move the needle, the device can be tuned electrostatically by the distance of the needle to the surface of the device. In a similar fashion, it is possible to test semiconductor material by applying a voltage to a needle and moving it close, but not in contact with, the semiconductor substrate. By applying and changing an electric potential on the needle, an area on the substrate can be gated (in a non-limiting example, a device area on the substrate can be gated). Given the teachings herein, the skilled artisan can adapt techniques known, for example, from scanning tunneling microscopy or scanning force microscopy to the cited techniques. In addition, standard measurement configurations and techniques, such as spreading resistance, van der Pauw, 4 probe sheet resistance and the like, and using the direct contacting of material without the need for structuring can be a useful way to characterize specific thin films since these measurements need equidistant needles. Moreover, when the needle is not in contact with a pad or surface of the device under test, the needle may serve as an antenna during testing and the taking of measurements. For example, a microwave current may be applied to the needle to cause the needle to emit a microwave signal. The needle may then be brought close to, for example, a qubit on the chip as part of a test and measurement process. It is noted that, in example embodiments, the engagement of the chip by the second end of probe needle is set according to testing requirements, chip layout, chip size, chip design, number of chips being tested and the like.

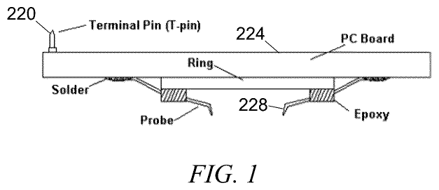

FIG. 1 illustrates the components of a conventional probe card. Probes 228 are mounted on a printed circuit board 224 and are connected to terminal pins 220 to transport test and measurement signals from a device under test to external equipment.

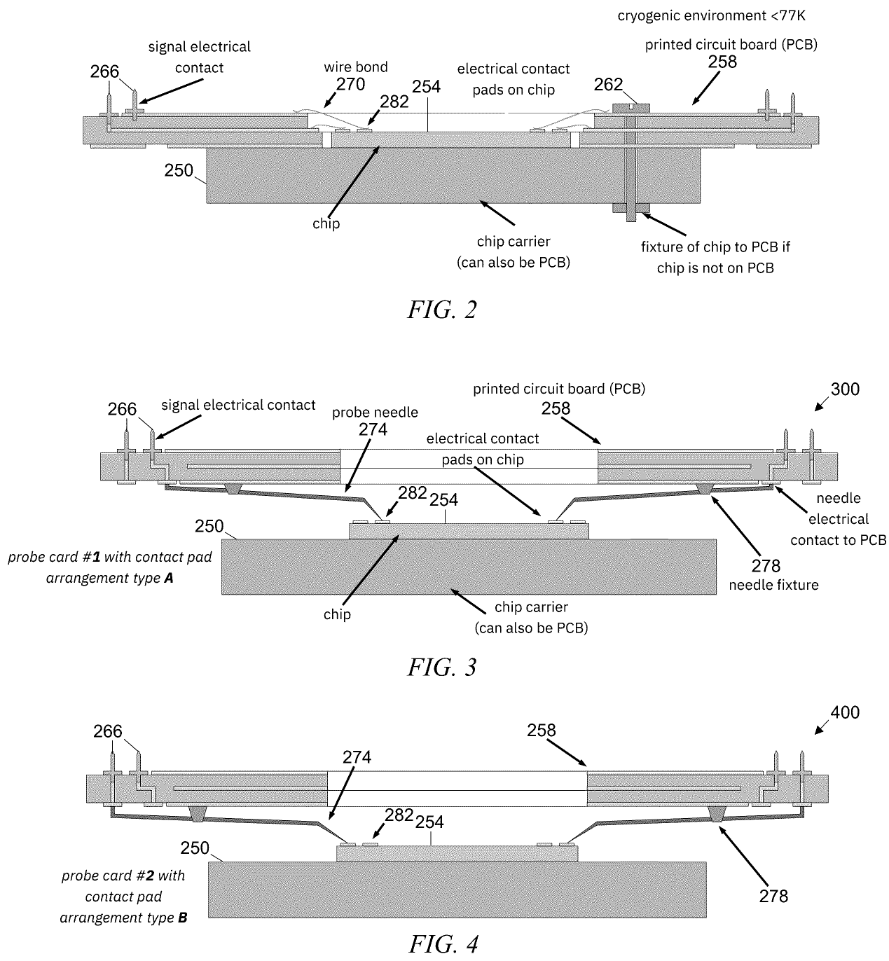

FIG. 2 illustrates an example standard cryogenic device characterization platform with a fixed chip to board interface (no probe card). A chip 254 is mounted on a chip carrier 250 (or printed circuit board (PCB)) for support. A retaining device 262 may be utilized to attach the chip carrier 250 to a PCB 258 that provides connectivity between pads 282 on the chip 254 and signal electrical contacts 266. The connection to the pads 282 can be implemented via wire bonds 270. The signal electrical contacts 266 enable connectivity with external circuitry, such as test and measurement electronics.

FIG. 3 illustrates a conventional technique for interfacing to a chip 254 under test in a cryogenic environment (for example, under 77 Kelvin (K)) with a first fixed probe card 300. As opposed to wire bonds 270, the technique of FIG. 3 utilizes probe needles 274 to implement connectivity between pads 282 on the chip 254 and the signal electrical contacts 266. The probe needles 274 make electrical contact with the bond pads 282 while the chip carrier 250 and the first fixed probe card 300 are positioned next to each other. Note the needle fixture 278.

FIG. 4 illustrates a conventional technique for interfacing to a chip 254 under test in a cryogenic environment with a second fixed probe card 400. The second fixed probe card 400 operates similar to the first fixed probe card 300 of FIG. 3, although the probe needles 274 are configured to connect with bond pads 282 residing in different locations on the chip 254.

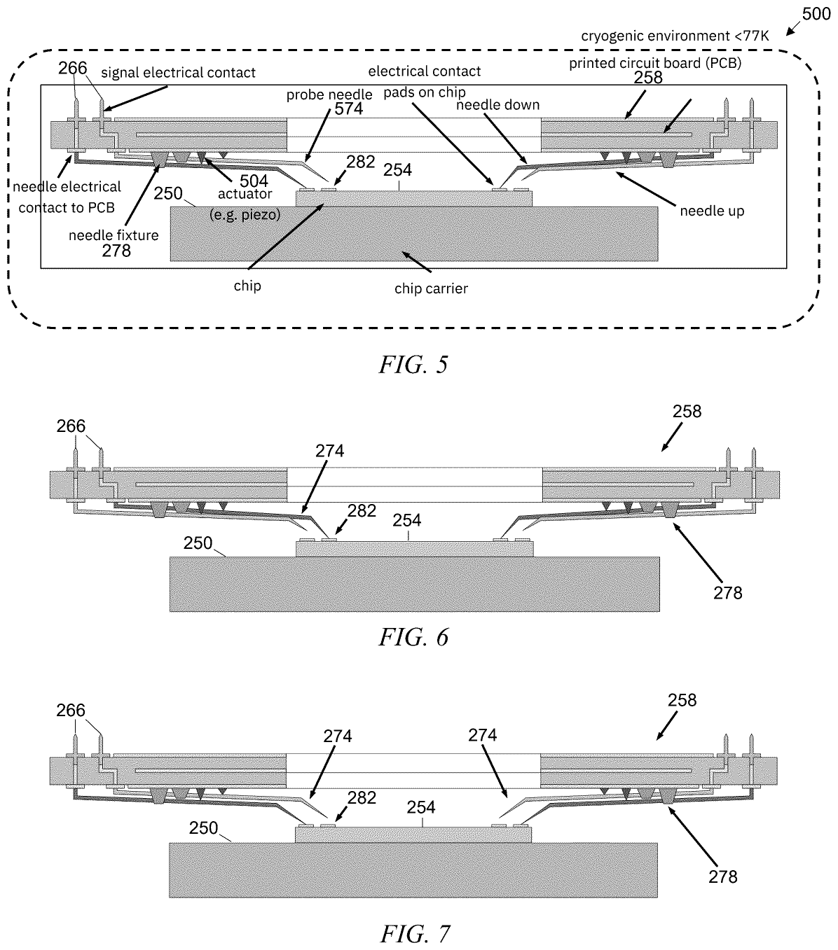

FIG. 5 is an overview of a reconfigurable probe card 500, in accordance with example embodiments. In example embodiments, actuators 504 are configured to lower or raise a corresponding retractable needle 574. (In example embodiments, each retractable needle 574 is configured to conform to a specified shape (corresponding to either a lowered or raised position) and the actuator 504 is configured to only move the corresponding retractable needle 574 to the corresponding opposite position. In example embodiments, the retractable needles 574 are configured as a micro-cantilever and/or are implemented with a superconducting material. Example retractable needles 574 that have only a small movement via the actuators inherently address needle planarization, which has to be performed in building a probe card with fixed needles, and which is not needed with the reconfigurable probe card 500.

The retractable needles 574 may be configured as part of an electrical component, e.g. an electron spin resonance (ESR) line and the like.) In example embodiments, it is pertinent that the retractable needles 574 are manufactured from specific material. In the example of the ESR line test, it is important that the retractable needles 574 are manufactured from a superconducting material. Since the retractable needles 574 are reconfigurable, needles 574 with different functionality can be activated and deactivated in-situ in a controlled way. Thus, the probe card 500 can be configured to provide the functionality of (and serve as) fixed probe card 300 in one configuration and fixed probe card 400 in another configuration. FIG. 6 illustrates the reconfigurable probe card 500 configured to serve as fixed probe card 300. FIG. 7 illustrates the reconfigurable probe card 500 configured to serve as fixed probe card 400. It is noted that the actuators used in example embodiments operate properly at cryogenic temperatures and that actuators used on conventional probe cards are not believed to operate properly at cryogenic temperatures.

The retractable needles 574 can be configured for a given device, to conduct a measurement on a portion of the given device (such as to characterize or troubleshoot a device) and the like. In example embodiments, an array of configurable needles 574 can cover a larger segment of a given area, including an area covering multiple devices, to avoid/minimize repositioning of card. Again, advantageously, if the array of needles 574 covers the full chip/wafer only the needles 574 have to move, not the chip in respect to the probe card 500.

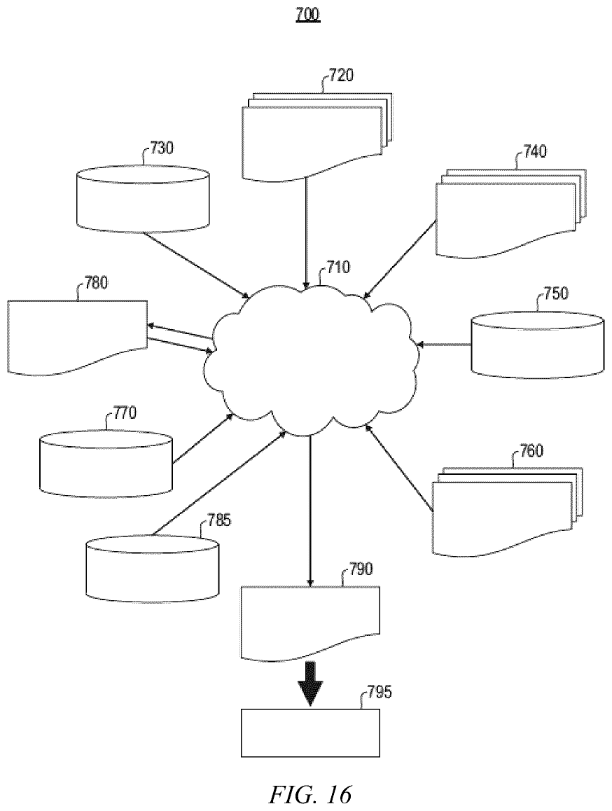

In example embodiments, circuitry, such as controller 520, can reside on the probe card to enable, for example, system-level testing. System-level testing includes testing a plurality of chips 254 together where the tests can include a combined measurement of a plurality of devices on the chips 254, a plurality of chips 254 or both. As described herein, the system-level testing can include chips 254 having different heights. In example embodiments, a multiplexer residing on the probe card assists in reconfiguring a measurement setup of the probe card (enabling the ability to completely disconnect unused needles 574 from measurement circuit and external noise sources). Given the teachings herein, the skilled artisan will be able to provide the controller by adapting known techniques (e.g., in digital circuitry). To implement digital circuitry, computer-aided semiconductor integrated circuit (IC) logic design, simulation, test, layout, and/or manufacture can be employed, as discussed below with respect to FIG. 16. The skilled artisan can synthesize digital logic circuits to carry out desired control and other functionality, using known computer-aided design techniques. The controller carries out functions as defined herein; given the teachings and description of the functions herein, known control circuit technologies can be employed; e.g., multicycle or pipelined, hardwired or microprogrammed, using any suitable technology family (e.g., 7 nm CMOS, 5 NM CMOS, and the like). For example, the specified functions can be instantiated in logic circuitry using a known design flow process used for example, in semiconductor IC logic design, simulation, test, layout, and manufacture.

Example embodiments provide measurement feedback for semiconductor and quantum devices at quantum temperatures and cryogenic temperatures. This enables the measurement of hundreds of devices residing on one or more chips 254 within one cool down of the cryostat.

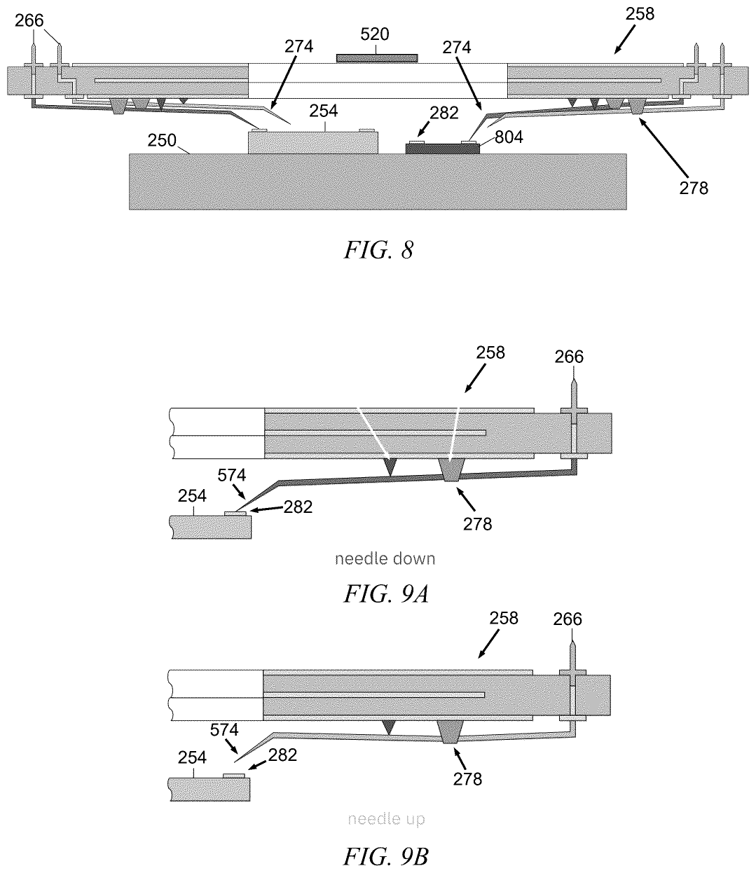

FIG. 8 illustrates the reconfigurable probe card 500 configured to probe heterogenous chips 254, 804, such as chips 254, 804 having different thicknesses, in accordance with example embodiments. As illustrated in FIG. 8, the height of the retractable needles 274 of the reconfigurable probe card 500 is adjustable to the height of the substrate and can adapt to chips 254, 804 having different widths, which allows pre-packaged testing of different chiplet combinations. This may be accomplished by 1) using actuators that can be adjusted to different heights; 2) using retractable needles 274 whose natural position provides electrical contact with the bond pads 282 of either the thickest or thinnest chips 254, 804; using actuators that move between two maximum positions; or any combination thereof. Contacting multiple chips 254, 804 of different height and pad patterns are also supported. In example embodiments, a controller 520 maps a specified height setting of the actuator 504 to a specified value for the corresponding control signal. The mapping can be determined by experiment (such as by putting the needle 574 in contact with a pad or surface of the chip 254, 804 and then raising the needle 574 until contact is lost), by equations that characterize the actuator and the like. In example embodiments, the controller 520 is configured to control test activities for the chip 254 under test, including configuring retractable needles 574. In example embodiments, the controller 520 includes electronic circuitry, such as a switching matrix, configured to connect the retractable needles 574 to each other, to external circuitry and the like.

To measure the height of the needle using the electrostatic technique (the needle acting as an antenna), for small distances between the needle and the chip surface, techniques inherited from scanning probe microscopy can be employed. For example, oscillate the needle and determine the interaction with the surface from a resonance frequency shift, or look at the deflection of a needle/probe or any other separation sensitive measure on the probe or on the chip. The electrostatic interaction with the sample surface can also be used if the sample is homogeneous and sensitive to the presence of the probe. In some instances, some force feedback might be necessary for accurate positioning/calibration of the probes. For larger distances between the needle and chip surface (e.g. the step height of a chiplet), it is possible to use a simple calibration of the distance vs. (for example) piezo voltages that move the needle, or a position sensitive measurement could be added. These aspects are not necessarily needed for all modes of operation. If used as an antenna to, e.g., manipulate a transistor or qubit on the chip surface, the power that arrives at the device can be a measure for the distance of the antenna/probe to the device.

FIGS. 9A-9B illustrate a retractable needle 574 in the down and up positions, respectively, in accordance with example embodiments. As described above, in the down position (see FIG. 9A), the retractable needle 574 makes electrical contact with the bond pad 282 and, in the up position (see FIG. 9B), the retractable needle 574 is electrically isolated from the bond pad 282.

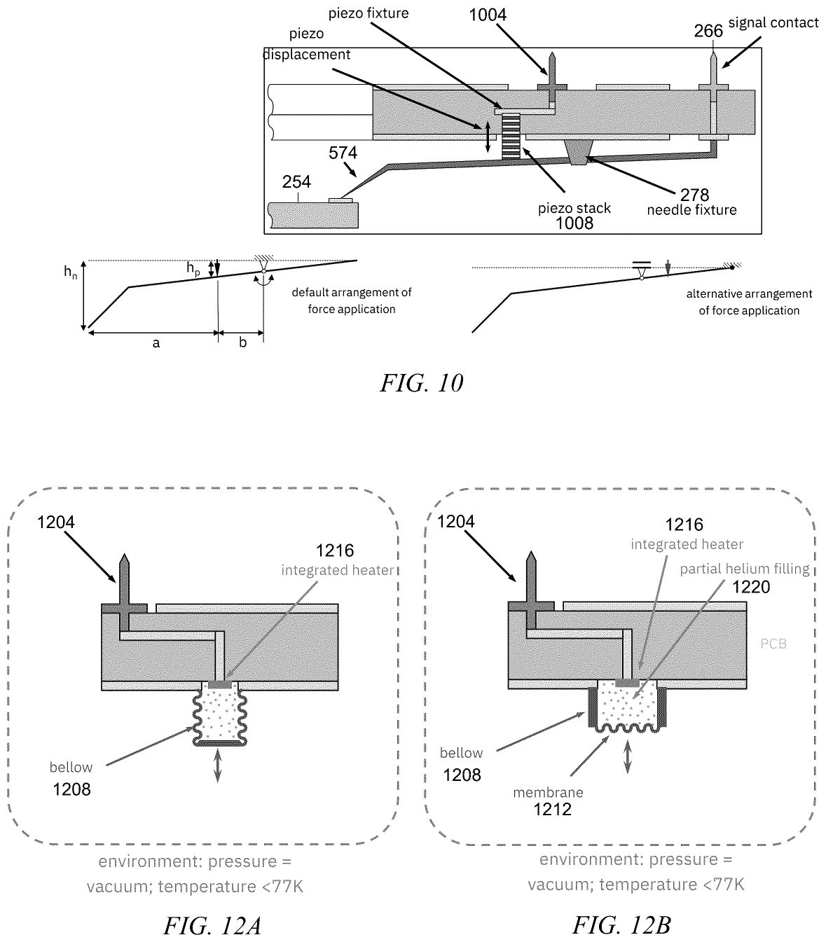

FIG. 10 illustrates a first example embodiment of the reconfigurable probe card 500 incorporating a stacked piezo 1008 actuated retractable needle 574. A power contact 1004 enables a control signal to actuate the piezo 1008 and the corresponding retractable needle 574. One or more exemplary embodiments employ a 2×2×2 millimeter (mm) piezo with 2 micrometers (μm) (Δhₚ) displacement @ 150 volts (V) (dissipationless). The result is ˜20 μm (Δhₙ) travel of the needle tip for a 10:1 ratio of a:b, as illustrated in FIG. 10.

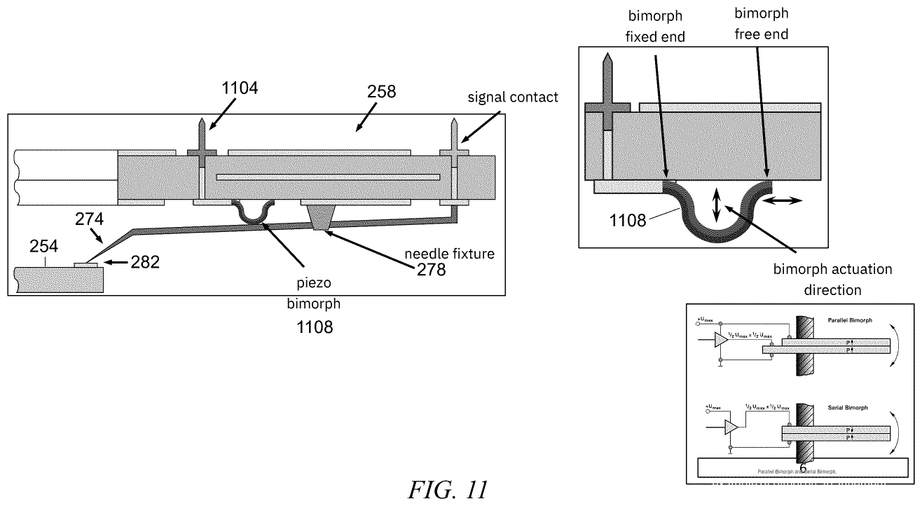

FIG. 11 illustrates a second example embodiment of the reconfigurable probe card 500 incorporating a thin film piezo bimorph 1108 (or bi-metal) actuated retractable needle 274, in accordance with example embodiments. The thin film piezo bimorph 1108 (or bi-metal) actuator can be controlled using different techniques. In example embodiments, a bias voltage is applied to each layer of the actuator 1108 via a power contact 1104 and the bias voltage is varied to change the length and, more importantly, height of the thin film piezo bimorph 1108 (or bi-metal) actuator, thereby adjusting the location of the tip of the retractable needle 574.

FIGS. 12A-12B illustrate a third example embodiment of the reconfigurable probe card 500 incorporating a bellows 1208 actuated retractable needle 574, in accordance with example embodiments. The bellows 1208 takes advantage of the low temperature environment of a cryostat and operates based on volumetric expansion (in one or more embodiments, the membrane 1212 should be implemented with a material that is elastic at cryogenic temperatures). In example embodiments, an integrated heater 1216 is controlled via a heater control voltage administered via a heater control pin 1204 and controls the volume of the gas filling 1220 of the bellows 1208. The heater 1216 can be implemented with a resistor and may be heated to approximately 5 Kelvin (K). In a non-limiting example, helium gas is used to fill the bellows 1208, although other gases are contemplated. The gas expands and shrinks to change the height (see FIG. 12A) or width (se FIG. 12B) of the bellows 1208, thereby adjusting the location of the tip of the retractable needle 574. The dimensions of the bellows 1208 may be incrementally adjusted by varying the temperature of the gas, varying a temperature gradient of the gas, or both. In certain instances, the gas converts to a liquid form at lower temperatures. It is noted that the application of the bellows 1208 to other environments and systems where actuators are utilized (e.g., other cryogenic activation applications) is also contemplated.

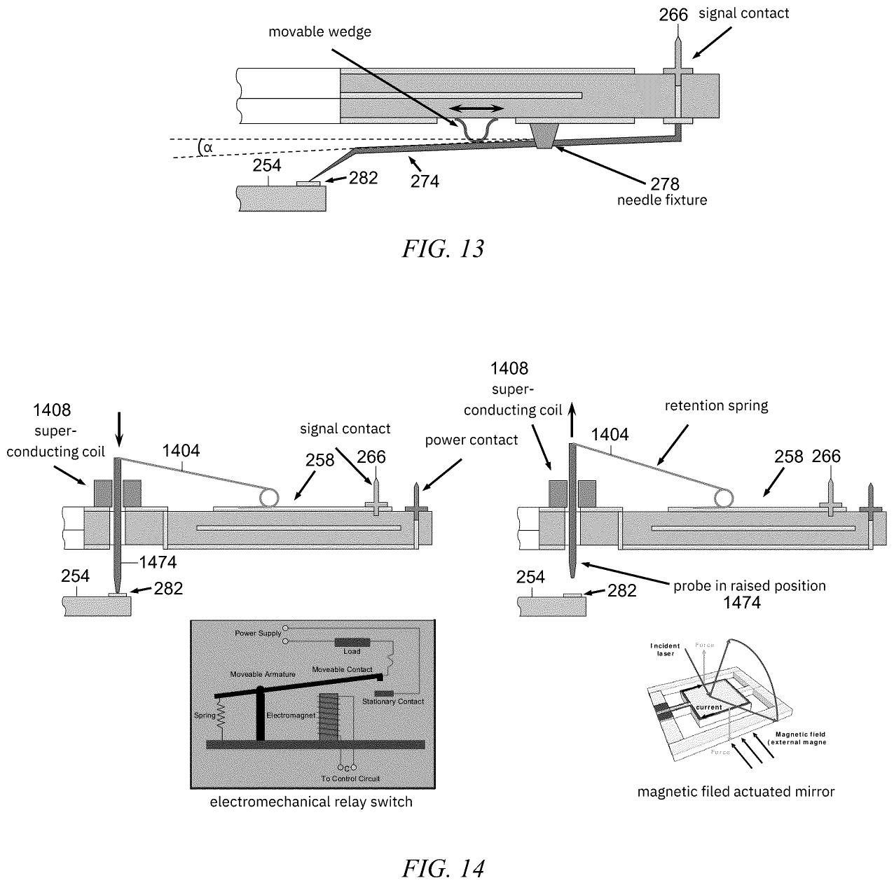

FIG. 13 illustrates a fourth example embodiment of the reconfigurable probe card 500 incorporating a movable wedge 1304 actuated retractable needle 274, in accordance with example embodiments. An actuator (not shown), such as the actuators depicted in FIGS. 10-12, can be incorporated to horizontally move the wedge 1304, thereby adjusting the location of the tip of the retractable needle 274. The embodiment of FIG. 13 can be configured to save space as the actuator can be located remotely from the wedge 1304. Since the wedge 1304 is relatively small compared to the actuator, the retractable needles 274 can therefore be located closer together than with other embodiments.

FIG. 14 illustrates a fifth example embodiment of the reconfigurable probe card 500 incorporating a coil 1408 actuated retractable needle 1474, in accordance with example embodiments. A retention spring 1404 pushes the retractable needle 1474 down towards the bond pad 282. Magnetic actuation of the retractable needle 1474 is performed either directly or in a manner similar to an electromechanical relay switch by adjusting a current through the coil 1408, such as a superconducting coil.

In example embodiments, if a physical strain develops on the retractable needles, a safe mode can be enacted that lifts the retractable needles and removes the risk of inappropriately bending the retractable needles.

Given the discussion thus far, it will be appreciated that, in general terms, an exemplary method, according to an aspect of the invention, includes the operations of cooling a cryostat to cryogenic temperatures; configuring a set of retractable needles 574 of a probe card according to a test plan for a given device during testing at the cryogenic temperatures; and testing the given device using the set of retractable needles 574.

In example embodiments, one or more of the retractable needles 574 are reconfigured in accordance with the test plan.

In example embodiments, the given device is a classical device.

In example embodiments, the given device is a quantum device.

In example embodiments, the configuring the set of retractable needles 574 according to the test plan further comprises configuring a subset of the retractable needles 574 according to the test plan for a second given device and the testing the given device using the set of retractable needles 574 further comprises testing the given device in conjunction with testing the second given device.

In one aspect, a probe card 500 comprises a printed circuit board 258 configured to transfer electrical signals to test and measurement circuitry; a plurality of retractable needles 574 mounted on the printed circuit board 258 and configured to transfer the electrical signals from a chip 254 via the printed circuit board 258; and a plurality of actuators 504 mounted on the printed circuit board 258, each actuator 504 configured to operate at cryogenic temperatures, engage a corresponding retractable needle 574 of the plurality of retractable needles 574 and to adjust a position of the engaged retractable needle 574 to contact a pad 282 on the chip 254.

In example embodiments, the actuator is selected from a group consisting of a stacked piezo device 1008, a thin film piezo bimorph device, a bi-metal actuated device, a bellows 1208 and a movable wedge 1304.In example embodiments, the actuator includes a stacked piezo device 1008.

In example embodiments, the actuator 1108 is a thin film piezo bimorph device or a bi-metal actuated device and the actuator 1108 is configured to change a length and a height of the actuator 1108 via a bias voltage applied to each layer of the actuator 1108, thereby adjusting a location of a tip of a corresponding retractable needle 574 based on the bias voltage.

In example embodiments, the actuator is a bellows 1208 configured to operate based on volumetric expansion, wherein the bellows 1208 comprises an integrated heater 1216 configured to be controlled via a heater control voltage and wherein the integrated heater 1216 is configured to control a volume of a gas filling 1220 of the bellows 1208.

In example embodiments, the actuator comprises a movable wedge 1304.

In example embodiments, each retractable needle 574 is adjustable on a vertical axis.

In example embodiments, the printed circuit board 258 has electronic lines configured to carry signals to control the actuators 504 and to carry signals from and to the retractable needles 574.

In example embodiments, the retractable needles 574 are configured as a micro-cantilever.

In example embodiments, the retractable needles 574 are implemented with a superconducting material.

In example embodiments, a controller 520 is configured to map a specified location of the actuator 504 to a specified control signal for a corresponding actuator 504.

In example embodiments, the actuator is a superconducting coil 1408 configured to adjust a height of a corresponding retractable needle 1474 in relation to a surface of the chip 254.

In example embodiments, a retention spring 1404 is configured to push down the retractable needle 1474.

In example embodiments, electronic circuitry 520 is configured to enable system-level testing.

In example embodiments, a height of at least one of retractable needles 574, in relation to a surface of the chip 254, is adjustable to adapt to chips 254, 804 with different thicknesses.

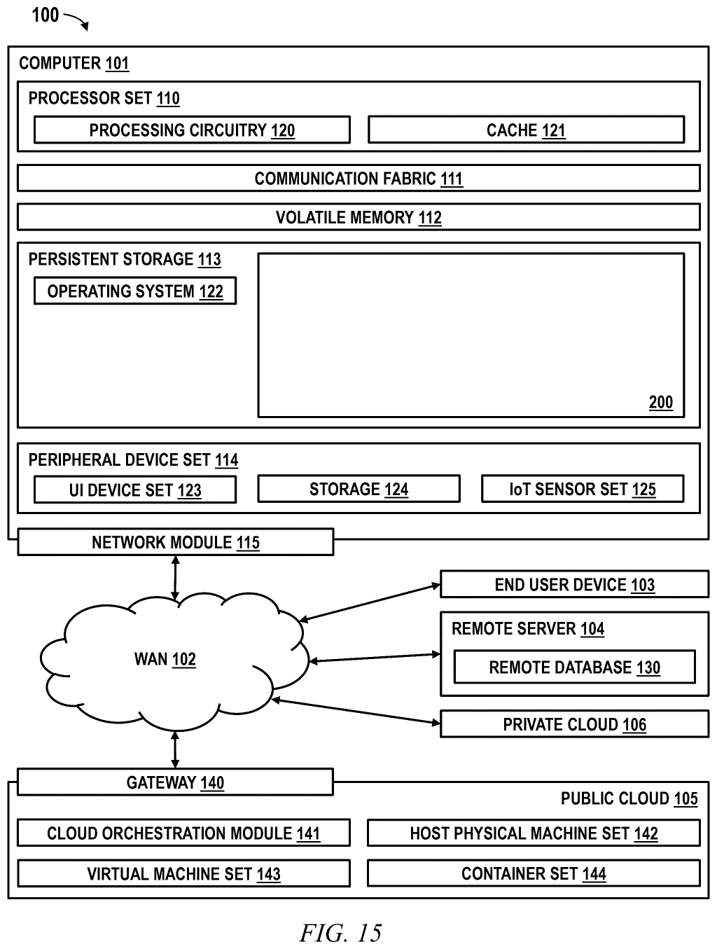

In one aspect, a system comprises a chip 254 under test; a controller configured to control test activities for the chip 254 under test; and a probe card 500 comprising a printed circuit board 258 configured to transfer electrical signals to test and measurement circuitry; a plurality of retractable needles 574 mounted on the printed circuit board 258 and configured to transfer the electrical signals from the chip 254 via the printed circuit board 258 under a control of the controller; and a plurality of actuators 504 mounted on the printed circuit board 258, each actuator 504 configured to operate at cryogenic temperatures, engage a corresponding retractable needle 574 of the plurality of retractable needles 574 and to adjust a position of the engaged retractable needle 574 to contact a pad 282 on the chip 254.

[Refer now to FIG. 15.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as test and measurement system 200. In example embodiments, the test and measurement system 200 includes control software for controlling the testing of a device, such as configuring the retractable needles 574. In example embodiments, the computer 101 with system 200 connects to the probe card via network module 115 and WAN 102, or alternative connections such as wirelessly, via a cable, and the like. Block 200 could also include software to carry out/control the processes in FIG. 16. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 15. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

### Exemplary Design Process Used in Semiconductor Design, Manufacture, and/or Test

One or more embodiments make use of computer-aided semiconductor integrated circuit design simulation, test, layout, and/or manufacture. In this regard, FIG. 16 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 16 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A probe card comprising:
a printed circuit board configured to transfer electrical signals to test and measurement circuitry;
a plurality of retractable needles mounted on the printed circuit board and configured to transfer the electrical signals from a chip via the printed circuit board; and
a plurality of actuators mounted on the printed circuit board, each actuator configured to operate at cryogenic temperatures, engage a corresponding retractable needle of the plurality of retractable needles and to adjust a position of the engaged retractable needle to contact a pad on the chip.

2. The probe card of claim 1, wherein the actuator includes a stacked piezo device.

3. The probe card of claim 1, wherein the actuator is a thin film piezo bimorph device or a bi-metal actuated device and wherein the actuator is configured to change a length and a height of the actuator via a bias voltage applied to each layer of the actuator, thereby adjusting a location of a tip of a corresponding retractable needle based on the bias voltage.

4. The probe card of claim 1, wherein the actuator is a bellows configured to operate based on volumetric expansion, wherein the bellows comprises an integrated heater configured to be controlled via a heater control voltage and wherein the integrated heater is configured to control a volume of a gas filling of the bellows.

5. The probe card of claim 1, wherein the actuator comprises a movable wedge.

6. The probe card of claim 1, wherein each retractable needle is adjustable on a vertical axis.

7. The probe card of claim 1, wherein the printed circuit board has electronic lines configured to carry signals to control the actuators and to carry signals from and to the retractable needles.

8. The probe card of claim 1, wherein the retractable needles are configured as a micro-cantilever.

9. The probe card of claim 1, wherein the retractable needles are implemented with a superconducting material.

10. The probe card of claim 1, further comprising a controller configured to map a specified location of the actuator to a specified control signal for a corresponding actuator 504.

11. The probe card of claim 1, wherein the actuator is a superconducting coil configured to adjust a height of a corresponding retractable needle in relation to a surface of the chip.

12. The probe card of claim 11, further comprising a retention spring configured to push down the retractable needle.

13. The probe card of claim 1, further comprising electronic circuitry configured to enable system-level testing.

14. The probe card of claim 1, wherein a height of at least one of retractable needles, in relation to a surface of the chip, is adjustable to adapt to chips with different thicknesses.

15. A method comprising:
cooling a cryostat to cryogenic temperatures;
configuring a set of retractable needles of a probe card according to a test plan for a given device during testing in the cryostat at the cryogenic temperatures; and
testing the given device using the set of retractable needles.

16. The method of claim 15, further comprising reconfiguring one or more of the retractable needles in accordance with the test plan.

17. The method of claim 15, wherein the given device is a classical device.

18. The method of claim 15, wherein the given device is a quantum device.

19. The method of claim 15, wherein the configuring of the set of retractable needles according to the test plan further comprises configuring a subset of the retractable needles according to the test plan for a second given device and wherein the testing of the given device using the set of retractable needles further comprises testing the given device in conjunction with testing the second given device.

20. A system comprising:
a chip under test;
a controller configured to control test activities for the chip under test; and
a probe card comprising:
a printed circuit board configured to transfer electrical signals to test and measurement circuitry;
a plurality of retractable needles mounted on the printed circuit board and configured to transfer the electrical signals from the chip via the printed circuit board under a control of the controller; and
a plurality of actuators mounted on the printed circuit board, each actuator configured to operate at cryogenic temperatures, engage a corresponding retractable needle of the plurality of retractable needles and to adjust a position of the engaged retractable needle to contact a pad on the chip.
